(19) United States
(12) Patent Application Publication
(10) Pub. No.: US 2025/0318157 A1
(43) Pub. Date: Oct. 9, 2025

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Chun-Ya Chiu, Tainan City (TW); Po-Kuang Hsieh, Kaohsiung City (TW); Chin-Hung Chen, Tainan City (TW); Ssu-I Fu, Kaohsiung City (TW); Yu-Hsiang Lin, New Taipei City (TW)

(73) Assignee: UNITED MICROELECTRONICS CORP., Hsin-Chu City (TW)

(21) Appl. No.: 18/661,704

(22) Filed: May 12, 2024

(30) Foreign Application Priority Data
Apr. 3, 2024 (TW) 113112681

(51) Int. Cl. H01L 29/94; H01L 21/768; H01L 23/528; H01L 29/66

(52) U.S. Cl. CPC H10D 1/665; H01L 21/76816; H01L 23/5283; H10D 1/047

(57) ABSTRACT

A semiconductor device includes a trench, a capacitor structure and a dielectric layer. The trench is formed in a substrate. The capacitor structure is disposed in the trench. The capacitor structure includes a bottom electrode layer, an insulating layer and a top electrode layer. The bottom electrode layer is disposed in the trench and on a top surface of the substrate. The insulating layer is disposed on the bottom electrode layer. The top electrode layer is disposed on the insulating layer. The dielectric layer is disposed on the top electrode layer. A portion of the dielectric layer is filled in the trench, and the dielectric layer includes a recessed portion disposed above the trench.

### BACKGROUND OF THE INVENTION

### 1. Field of the Invention

The present disclosure relates to the field of semiconductor devices, and more particularly, to a semiconductor device including a deep trench capacitor structure and a method for fabricating the same.

### 2. Description of the Prior Art

Due to capacitors capable of storing charges, the capacitors are widely applied to components of semiconductor devices such as memories. The conventional capacitors are planar capacitor structures. However, with the development of artificial intelligence (AI) and high performance computing (HPC), the desired capacitance value provided by the capacitors is increasing. In order to simultaneously satisfy the needs of AI and HPC and the trend of miniaturization of electronic components, deep trench capacitors gradually replaces planar capacitors. Accordingly, how to improve the structure and/or the fabricating method of the deep trench capacitors has become an important issue for relevant industry.

### SUMMARY OF THE INVENTION

According to one aspect of the present disclosure, a semiconductor device includes a trench, a capacitor structure and a dielectric layer. The trench is formed in a substrate. The capacitor structure is disposed in the trench. The capacitor structure includes a bottom electrode layer, an insulating layer and a top electrode layer. The bottom electrode layer is disposed in the trench and on a top surface of the substrate. The insulating layer is disposed on the bottom electrode layer. The top electrode layer is disposed on the insulating layer. The dielectric layer is disposed on the top electrode layer. A portion of the dielectric layer is filled in the trench, and the dielectric layer includes a recessed portion disposed above the trench.

According to another aspect of the present disclosure, a method for fabricating a semiconductor device includes steps as follows. A trench is formed in a substrate. A capacitor structure is formed in the trench, which includes steps as follows. A bottom electrode layer is formed in the trench and on a top surface of the substrate. An insulating layer is formed on the bottom electrode layer. A top electrode layer is formed on the insulating layer. A dielectric layer is formed on the top electrode layer, in which a portion of the dielectric layer is filled in the trench, and the dielectric layer includes a recessed portion disposed above the trench.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3, FIG. 4, FIG. 5 and FIG. 6 are schematic cross-sectional views showing steps of a method for fabricating a semiconductor device according to an embodiment of the present disclosure.

FIG. 7, FIG. 8, FIG. 9 and FIG. 10 are schematic cross-sectional views showing steps of a method for fabricating a semiconductor device according to another embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical reference signs or similar reference signs are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

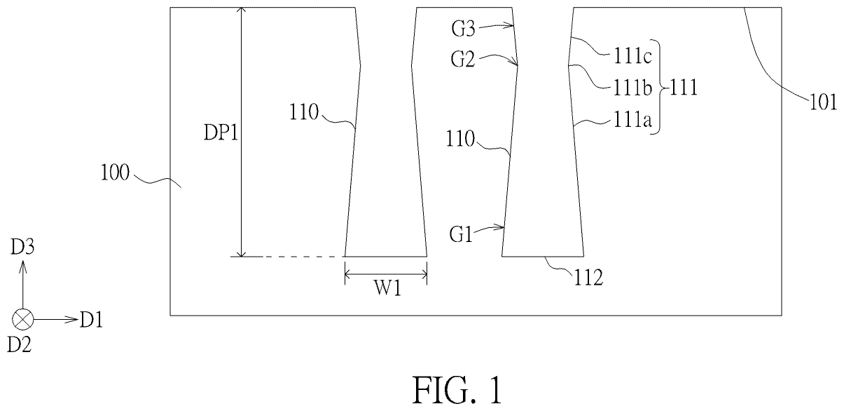

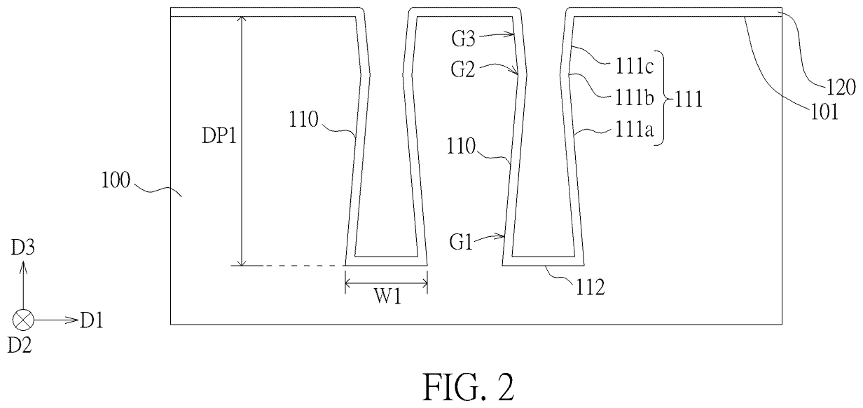

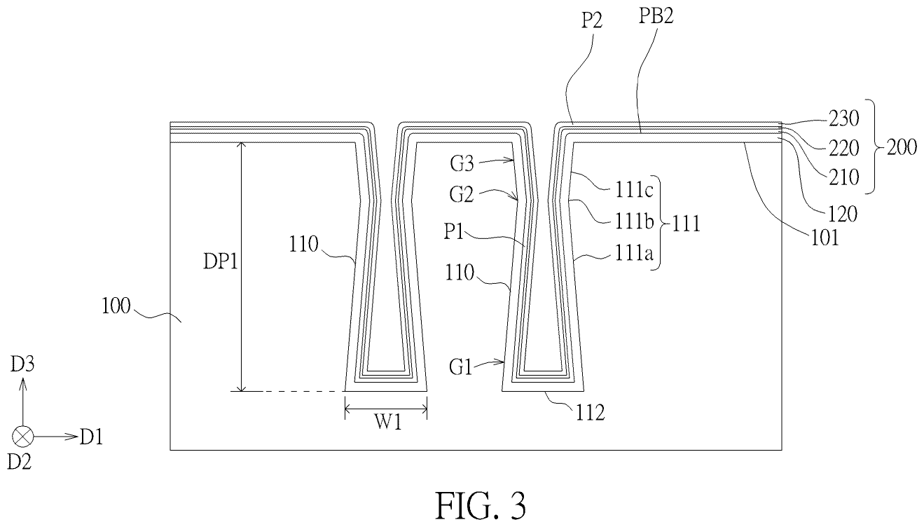

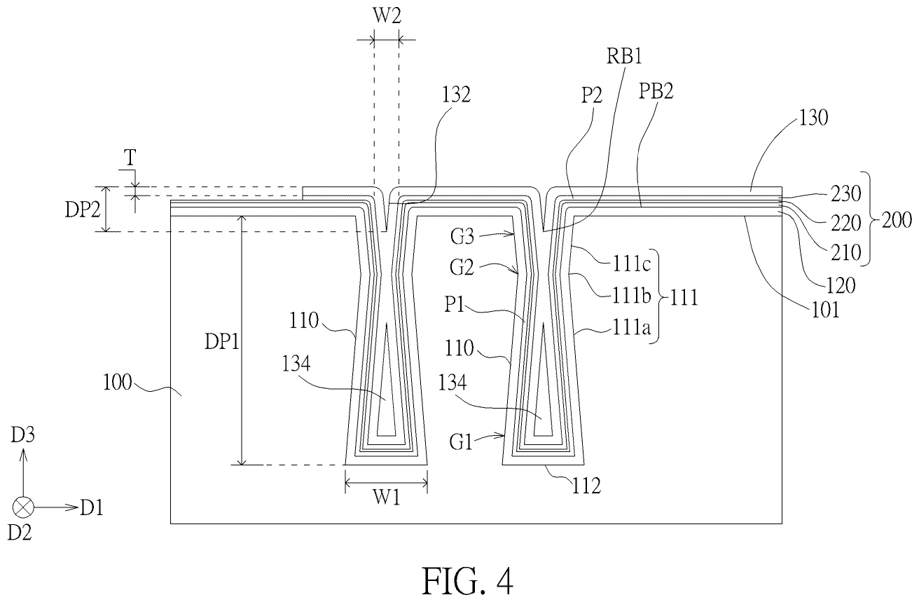

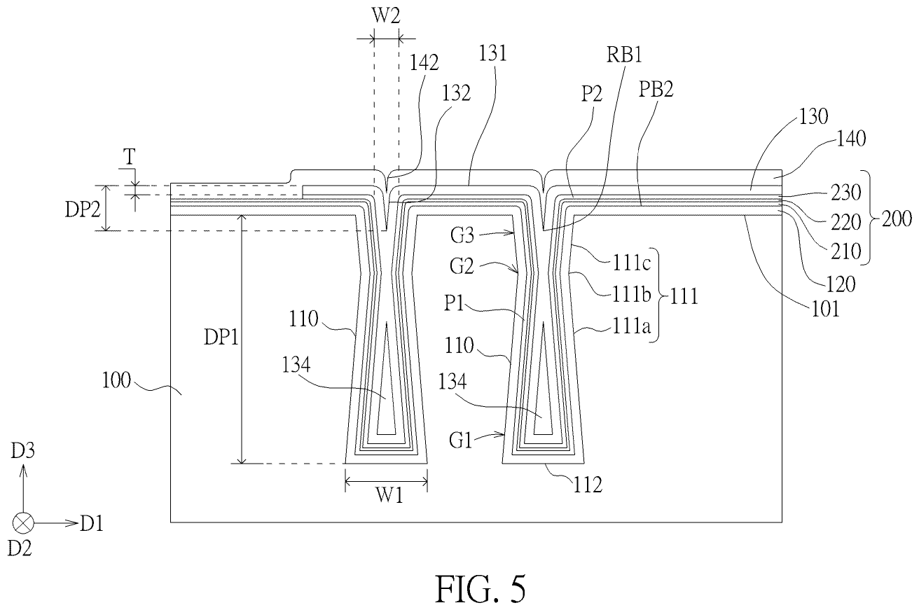

Please refer to FIG. 1 to FIG. 6, which are schematic cross-sectional views showing steps of a method for fabricating a semiconductor device according to an embodiment of the present disclosure. In FIG. 1, trenches 110 are firstly formed in a substrate 100. The substrate 100 may be a silicon substrate, an epitaxial silicon substrate, a silicon carbide substrate or a silicon on insulator (SOI) substrate. The trenches 110 may be formed by semiconductor processes, such as photolithography and etching processes.

The number of the trenches 110 may be one or plural. Herein, the number of the trenches 110 is exemplary two, and the two trenches 110 are arranged along the first horizontal direction D1. The number of the trenches 110 may be flexibly adjusted according to actual needs. For example, the number of the trenches 110 may be adjusted according to the desired capacitance value provided by the capacitor structure 200 formed later. The more the trenches 110, the larger the area of the capacitor structure 200, which is beneficial to increase the capacitance value of the capacitor structure 200.

The trench 110 has a width W1 in the first horizontal direction D1, the trench 110 extends along the second horizontal direction D2 and has a length in the second horizontal direction D2 (not shown). The length of the trench 110 may be greater than the width W1. The first horizontal direction D1 and second horizontal direction D2 are perpendicular to each other.

Specifically, the trench 110 includes a bottom wall 112 and two side walls 111. The two side walls 111 are disposed at two opposite sides of the bottom wall 112 along the first horizontal direction D1. Each of the side walls 111 includes a first inclined portion 111a, a bend portion 111b and a second inclined portion 111c from bottom to top. A first trench portion G1 is defined between the two first inclined portions 111a of the two side walls 111, a neck portion G2 is defined between the two bend portions 111b of the two side walls 111, and a second trench portion G3 is defined between the two second inclined portions 111c of the two side walls 111. In other words, the trench 110 may include the first trench portion G1, the neck portion G2, and the second trench portion G3 from bottom to top. In the first trench portion G1, the width W1 of the trench 110 gradually decreases from bottom to top along the vertical direction D3, and the first trench portion G1 has a trapezoidal cross section (which has a narrower top and a wider bottom). In the second trench portion G3, the width W1 of the trench 110 gradually increases from bottom to top along the vertical direction D3, and the second trench portion G3 has an inverted trapezoidal cross section (which has a wider top and a narrower bottom). The neck portion G2 is the portion of the trench 110 with a smallest width W1. In other words, the two side walls 111 of the trench 110 are not vertical side walls, and the width W1 of the trench 110 varies along the vertical direction D3.

The trench 110 has a depth DP1 in the vertical direction D3. The vertical direction D3 may be, for example, parallel to a normal direction (not shown) of the top surface 101 of the substrate 100 and perpendicular to the first horizontal direction D1 and the second horizontal direction D2. According to an embodiment of the present disclosure, the ratio of the depth DP1 to the width W1 of the trench 110 (i.e., the depth-to-width ratio) may be 23 to 27. Since the width W1 of the trench 110 varies along the vertical direction D3, the aforementioned depth-to-width ratio may be based on the largest width W1 of the trench 110. Thereby, the trench 110 of the present disclosure has a larger depth-to-width ratio. Compared with a trench having a smaller depth-to-width ratio (for example, 18 to 22), the present disclosure has advantages as follows. When a dielectric layer 130 which is formed later is filled into the trench 110, it is beneficial to allow the portions of the dielectric layer 130 on the right and left side walls 111 to contact and merge, and is beneficial for the dielectric layer 130 to form a recessed portion 132 located above the trench 110.

Next, as shown in FIG. 2, liner 120 may be optionally formed in trench 110 and on the top surface 101 of substrate 100. The liner 120 conformally covers the bottom wall 112 and the side walls 111 of each of the trenches 110 and the top surface 101 of the substrate 100. The material of the liner 120 is preferably an insulating material, such as silicon oxide.

Next, as shown in FIG. 3, a capacitor structure 200 is formed in the trench 110, which may include steps as follows. First, a bottom electrode layer 210 is formed in the trenches 110 and on the top surface 101 of the substrate 100, in which the bottom electrode layer 210 conformally covers the bottom wall 112 and the side walls 111 of each of the trenches 110 and the top surface 101 of the substrate 100 through the liner 120. Next, an insulating layer 220 is formed on the bottom electrode layer 210, in which the insulating layer 220 conformally covers the bottom electrode layer 210. Next, a top electrode layer 230 is formed on the insulating layer 220, in which the top electrode layer 230 conformally covers the insulating layer 220.

The materials of the bottom electrode layer 210 and the top electrode layer 230 may independently include conductive materials, such as metals of copper (Cu), chromium (Cr), titanium (Ti), tungsten (W), gold (Au), aluminum (Al), indium (In), tin (Sn), nickel (Ni), platinum (Pt), silver (Ag) or alloys thereof, but not limited thereto. According to an embodiment of the present disclosure, the materials of the bottom electrode layer 210 and the top electrode layer 230 includes titanium nitride (TiN). The material of the insulating layer 220 may include a high dielectric constant material. The insulating layer 220 may be a single layer structure or a composite structure formed by multiple film layers. According to an embodiment of the present disclosure, the insulating layer 220 may be a composite structure of ZrO₂/Al₂O₃/ZrO₂ (ZAZ). The capacitor structure 200 includes a first portion P1 disposed in the trenches 110 and a second portion P2 disposed on the top surface 101 of the substrate 100.

Next, as shown in FIG. 4, a dielectric layer 130 is formed on the top electrode layer 230, in which a portion of the dielectric layer 130 is filled in the trench 110, and the dielectric layer 130 includes a recessed portion 132 located above the trench 110. In some embodiments, when forming the dielectric layer 130 on the top electrode layer 230, the parameters of forming the dielectric layer 130 can be controlled to form voids 134 in the dielectric layer 130, and the voids 134 are located in the trenches 110. In the process of filling material layers (herein, the liner 120, the bottom electrode layer 210, the insulating layer 220 and the top electrode layer 230) into the trenches 110, stress may be gradually accumulated in the substrate 100, which may cause the fracture of the substrate 100. The voids 134 can buffer and absorb the stress, which may reduce the probability that the substrate 100 fractures during the process of accumulating stress.

Specifically, the dielectric layer 130 conformally covers the bottom wall 112 and the side walls 111 of each of the trenches 110 and the top surface 101 of the substrate 100 through the capacitor structure 200. Since the trench 110 has the neck portion G2 and/or a larger depth-to-width ratio, when the dielectric layer 130 is filled into the trench 110, the portions of the dielectric layer 130 located on the left and the right side walls 111 tend to contact and merge with each other. The merging of the portions of the dielectric layers 130 located on the left and the right side walls 111 particularly tends to occur at the neck portion G2, so that the portion of the dielectric layer 130 corresponding to the trench 110 is formed with a recessed portion 132. The recessed portion 132 may have a V-shaped cross section. The recessed portion 132 may have a width W2 and a depth DP2, and the ratio of the width W2 to the depth DP2 of the recessed portion 132 may be 1.5 to 1.9. According to an embodiment of the present disclosure, the ratio of the width W2 to the depth DP2 of the recessed portion 132 is 1.7. For example, the width W2 of the recessed portion 132 may be 250 nm, and the depth DP2 of the recessed portion 132 may be 146 nm.

In addition, when the width W1 of the trench 110 is smaller at the neck portion G2 or the depth-to-width ratio of the trench 110 is larger, the portions of the dielectric layer 130 on the two side walls 111 may merge at the neck portion G2 before the trench 110 is completely filled by the dielectric layer 130. As a result, the first trench portion G1 of the trench 110 is not completely filled by the dielectric layer 130, and the void 134 is formed in the dielectric layer 130. As mentioned above, the void 134 is beneficial to buffer and absorb a portion of the stress in the substrate 100. However, the present disclosure is not limited thereto. In other embodiments, the parameters of forming the dielectric layer 130 can be controlled or the width W1 of the trench 110 at the neck portion G2 may be increased, so that the first trench portion G1 of the trench 110 can be completely filled by the dielectric layer 130 without forming the void 134 in the dielectric layer 130.

The dielectric layer 130 may have a thickness T, and the thickness T may range from 200 angstroms to 500 angstroms. The materials of the dielectric layer 130 may include oxides, such as silicon dioxide or tetraethoxysilane (TEOS), but not limited thereto.

Please continue to refer to FIG. 4. Next, the size of the top electrode layer 230 is defined. Semiconductor processes, such as one or more photolithography and etching processes may be performed to remove a portion of the dielectric layer 130 and a portion of the top electrode layer 230 located outside the trench 110 to expose a portion of the insulating layer 220 of the capacitor structure 200.

Next, as shown in FIG. 5, a protective layer 140 may be formed on the dielectric layer 130 and the portion of the capacitor structure 200 not covered by the dielectric layer 130. The protective layer 140 may be, for example, a contact etch stop layer (CESL). The material of the protective layer 140 may include nitride, such as silicon nitride (SiN) or silicon carbide nitride (SiCN), but not limited thereto. Specifically, after the dielectric layer 130 is formed, a planarization process such as a chemical mechanical polishing (CMP) process on the dielectric layer 130 is omitted, and the protective layer 140 is directly formed on the dielectric layer 130 after the size of the top electrode layer 230 is defined. The recessed portion 132 of the dielectric layer 130 is reserved, and the protective layer 140 conformally covers the top surface 131 of the dielectric layer 130. The protective layer 140 can also be formed with a recessed portion 142 corresponding to the recessed portion 132, and the recessed portion 142 can also have a V-shaped cross section.

In the fabricating method including to perform a planarization process on the dielectric layer 130, when the dielectric layer 130 is first subjected to the planarization process and then other film layers (such as the protective layer 140) are formed thereon, the other film layers (such as the protective layer 140) directly covering the dielectric layer 130 are easy to peel off, and the performance of the semiconductor device 1 (see FIG. 6) may be affected or the production yield of the semiconductor device 1 may be reduced thereby. In addition, when performing the planarization process on the dielectric layer 130, another dielectric layer (not shown) is usually required to firstly deposited on the dielectric layer 130 as a sacrificial dielectric layer to increase the total thickness (i.e., the sum of the thickness of the dielectric layer 130 and the thickness the sacrificial dielectric layer) of the dielectric layers, so that the flatness of the dielectric layer 130 after the planarization process may be improved. However, the additional deposition process requires additional materials and time, the production cost is increased thereby. In the present disclosure, by omitting the planarization process on the dielectric layer 130, the peeling probability of other film layers directly covering the dielectric layer 130 (such as the protective layer 140) can be reduced significantly. Moreover, the process can be simplified, and the costs of material and time required for depositing the sacrificial dielectric layer are omitted, which is beneficial to reduce the production costs.

Next, as shown in FIG. 6, a dielectric layer 150 may be completely deposited on the substrate 100 to cover the protective layer 140. The material of the dielectric layer 150 may include oxides, such as silicon dioxide or tetraethoxysilane (TEOS). Next, a plug process is performed. Specifically, semiconductor processes such as photolithography and etching processes may be performed to remove a portion of the dielectric layer 150, a portion of the protective layer 140, and a portion of the insulating layer 220 to form a hole 152 to expose the bottom electrode layer 210, and further semiconductor processes such as photolithography and etching processes are performed to remove a portion of the dielectric layer 150, a portion of the protective layer 140 and a portion of the dielectric layer 130 to form a hole 154 to expose the top electrode layer 230. Next, conductive materials are filled into the holes 152 and 154 and a planarization process is performed to form a contact CT1 and a contact CT2 in the dielectric layer 150. The contact CT1 is electrically connected with the bottom electrode layer 210, and the contact CT2 is electrically connected with the top electrode layer 230. The conductive materials of the contact CT1 and the contact CT2 may be the same or different, and may independently include a barrier layer (not shown) and a metal layer (not shown). The material of the barrier layer may include titanium, tantalum, titanium nitride, tantalum nitride, nitrogen or a combination thereof. The material of the metal layer may include aluminum, titanium, tantalum, tungsten, niobium, molybdenum, copper or a combination thereof, but not limited thereto. Thereby, the fabrication of the semiconductor device 1 is completed.

Please refer to FIG. 6, which is a schematic cross-sectional view of the semiconductor device 1 according to an embodiment of the present disclosure. The semiconductor device 1 includes the trenches 110, the capacitor structure 200 and the dielectric layer 130. The trenches 110 are formed in the substrate 100. The capacitor structure 200 is disposed in the trenches 110. The capacitor structure 200 includes the bottom electrode layer 210, the insulating layer 220 and the top electrode layer 230. The bottom electrode layer 210 is disposed in the trenches 110 and on the top surface 101 of the substrate 100. The insulating layer 220 is disposed on the bottom electrode layer 210. The top electrode layer 230 is disposed on the insulating layer 220. The dielectric layer 130 is disposed on the top electrode layer 230, in which a portion of the dielectric layer 130 is filled in the trenches 110, and the dielectric layer 130 includes a recessed portion 132 located above the trench 110.

In this embodiment, the recessed portion 132 may have a V-shaped cross section. The recessed portion 132 has a width W2 and a depth DP2, and the ratio of the width W2 to the depth DP2 (width-to-depth ratio) may be 1.5 to 1.9. As shown in FIG. 6, since the width W2 of the recessed portion 132 varies in the vertical direction D3, the aforementioned width-to-depth ratio is based on the largest width W2. The capacitor structure 200 includes a first portion P1 disposed in the trenches 110 and a second portion P2 disposed on the top surface 101 of the substrate 100, and a bottom RB1 of the recessed portion 132 is lower than a bottom PB2 of the second portion P2. In some embodiments, the bottom RB1 of the recessed portion 132 may be aligned with the top surface 101 of the substrate 100.

In this embodiment, the dielectric layer 130 has a thickness T, and the thickness T may range from 200 angstroms to 500 angstroms. The dielectric layer 130 is formed with the voids 134, and the voids 134 are located in the trenches 110.

In this embodiment, the number of the trenches 110 is at least two, and the capacitor structure 200 is disposed in the at least trenches 110. Herein, the number of the trenches 110 is exemplary two, but not limited thereto. The number of the trenches 110 may also be one or greater than or equal to three. In the present disclosure, the capacitor structure 200 is disposed in a single trench 110 or a plurality of trenches 110, and thus is a deep trench capacitor structure. Compared with a planar capacitor structure, the area of the capacitor structure 200 can be increased by the depths DP1 of the trenches 110, so that a larger capacitance value can be provided. When increasing the number of the trenches 110, it is beneficial to increase the capacitance value of the capacitor structure 200.

The semiconductor device 1 may optionally further include the liner 120 disposed in the trenches 110 and on the top surface 101 of the substrate 100. The liner 120 is located between the substrate 100 and the capacitor structure 200. The semiconductor device 1 may optionally further include the protective layer 140 disposed on the dielectric layer 130 and a portion of the capacitor structure 200 not covered by the dielectric layer 130. The semiconductor device 1 may optionally further include the dielectric layer 150 disposed on the protective layer 140, and the semiconductor device 1 may optionally further include the contact CT1 electrically connected with the bottom electrode layer 210 and the contact CT2 electrically connected with the top electrode layer 230. For other details about the semiconductor device 1, reference may be made to the above description, and are not repeated herein.

Please refer to FIGS. 1, 2, 7 to 10, which are schematic cross-sectional views showing steps of a method for fabricating a semiconductor device according to another embodiment of the present disclosure. First, as shown in FIG. 1, trenches 110 are formed in a substrate 100. Next, as shown in FIG. 2, a liner 120 may be optionally formed in the trenches 110 and on the top surface 101 of the substrate 100.

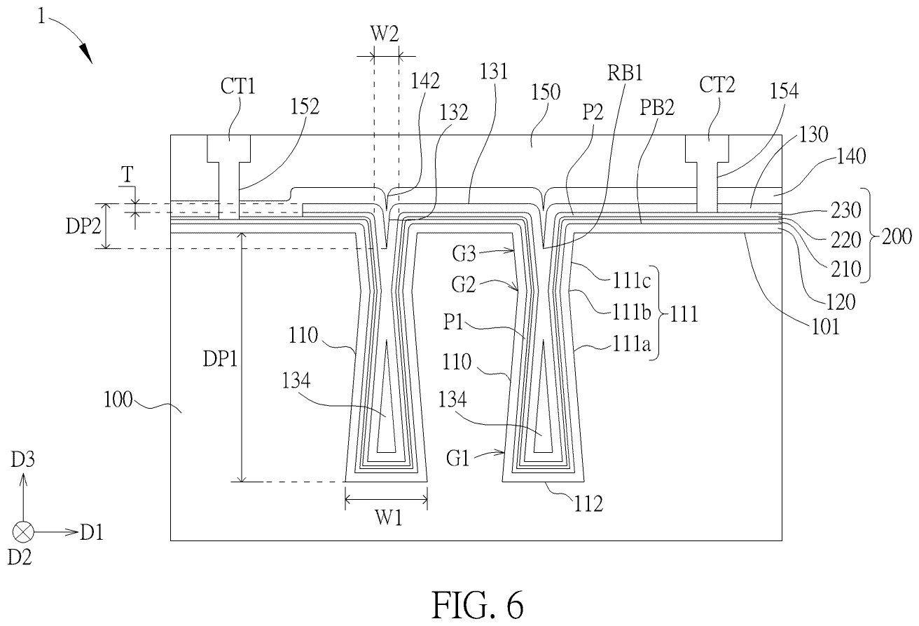

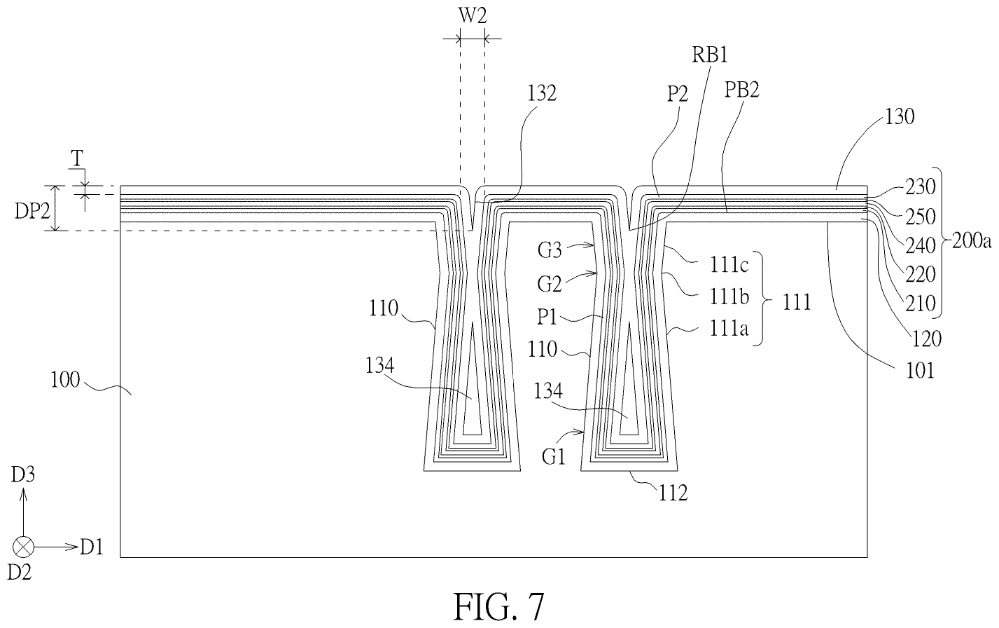

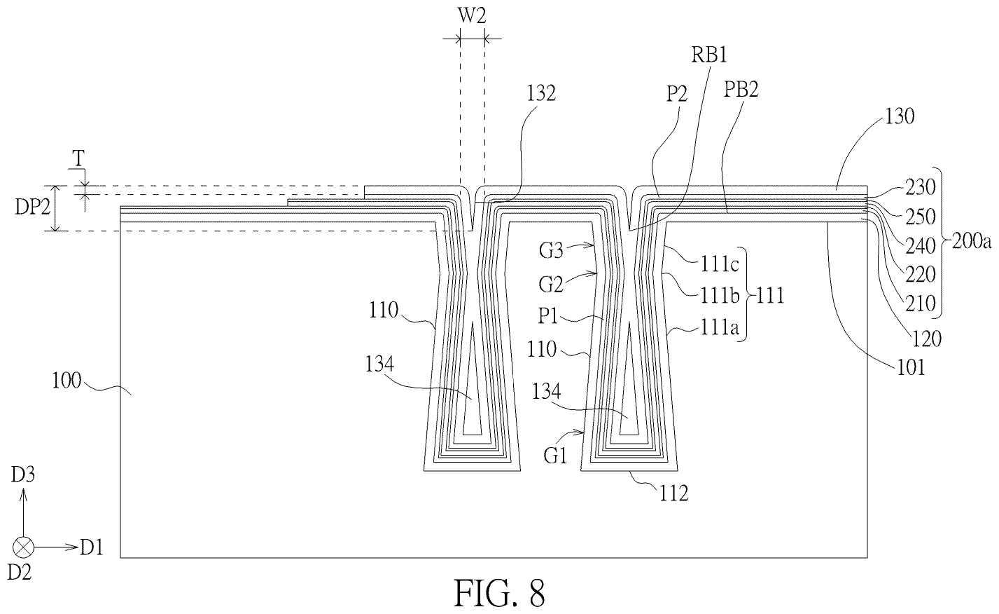

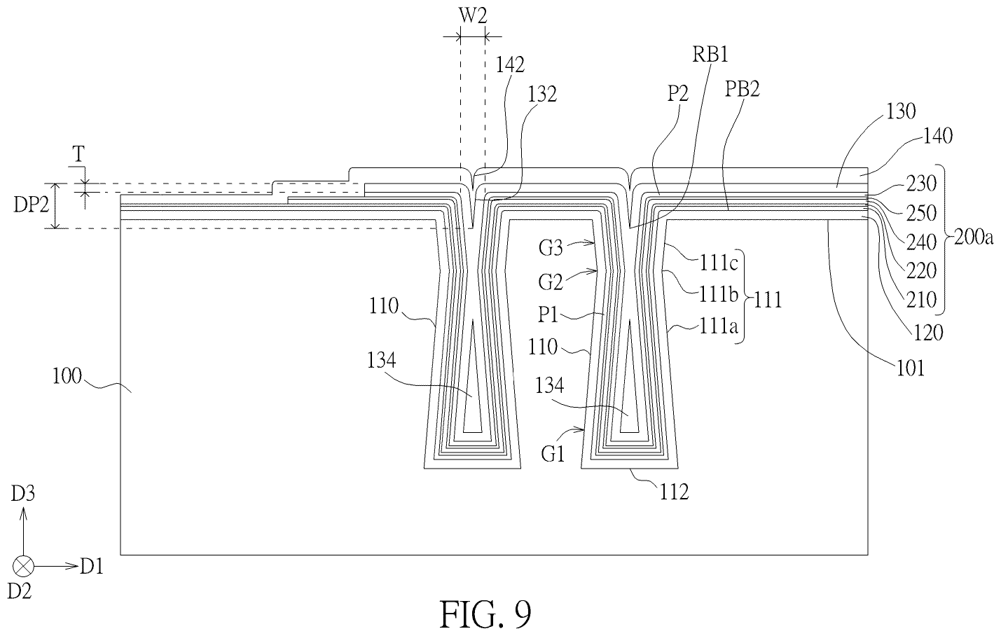

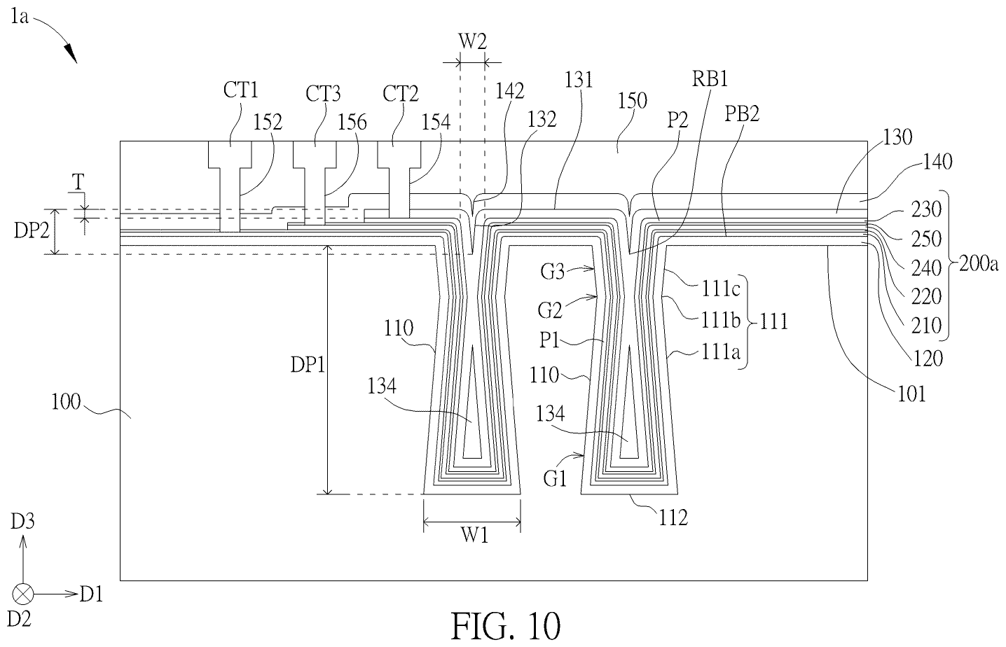

Next, as shown in FIG. 7, a capacitor structure 200a is formed in the trenches 110, which may include steps as follows. A bottom electrode layer 210 is formed in the trenches 110 and on the top surface 101 of the substrate 100. An insulating layer 220 is formed on the bottom electrode layer 210. A middle electrode layer 240 is formed on the insulating layer 220. An insulating layer 250 is formed on the middle electrode layer 240, and a top electrode layer 230 is formed on the insulating layer 250. For the material of the middle electrode layer 240, reference may be made to the relevant description of the bottom electrode layer 210 and the top electrode layer 230 above. According to an embodiment of the present disclosure, the material of the middle electrode layer 240 may include titanium nitride (TiN). For the material of the insulating layer 250, reference may be made to the relevant description of the insulating layer 220 above. According to an embodiment of the present disclosure, the insulating layer 250 may be a composite structure of ZrO₂/Al₂O₃/ZrO₂ (ZAZ). The capacitor structure 200a includes a first portion P1 disposed in the trenches 110 and a second portion P2 disposed on the top surface 101 of the substrate 100.

Next, a dielectric layer 130 is formed on the top electrode layer 230, in which a portion of the dielectric layer 130 is filled in the trenches 110, and the dielectric layer 130 includes a recessed portion 132 located above the trench 110. In some embodiments, when forming the dielectric layer 130 on the top electrode layer 230, voids 134 may be formed in the dielectric layer 130, and the voids 134 are located in the trenches 110.

Next, as shown in FIG. 8, the size of the top electrode layer 230 is defined, which may include steps as follows. Semiconductor processes such as one or more photolithography and etching processes may be performed to remove a portion of the dielectric layer 130 and a portion of the top electrode layer 230 located outside the trenches 110, so that a portion of the insulating layer 250 of the capacitor structure 200a is exposed. Next, the size of the middle electrode layer 240 is defined. Semiconductor processes such as one or more photolithography and etching process may be performed to remove a portion of the insulating layer 250 and a portion of the middle electrode layer 240 not covered by the dielectric layer 130 and the top electrode layer 230, so that the insulating layer 220 of the capacitor structure 200a is exposed. Thereby the capacitor structure 200a can include a stepped cross section.

Next, as shown in FIG. 9, a protective layer 140 may be formed on the dielectric layer 130 and on the portion of the capacitor structure 200a not covered by the dielectric layer 130. After the dielectric layer 130 is formed and before the protective layer 140 is formed, a planarization process such as a chemical mechanical polishing (CMP) process on the dielectric layer 130 is omitted, and the protective layer 140 is directly formed on the dielectric layer 130 after the size of the top electrode layer 230 is defined. The recessed portion 132 of the dielectric layer 130 is reserved, and the protective layer 140 conformally covers the top surface 131 (refer to FIG. 10) of the dielectric layer 130. The protective layer 140 can also be formed with a recessed portion 142 corresponding to the recessed portion 132. The recessed portion 142 may also have a V-shaped cross section.

Next, as shown in FIG. 10, a dielectric layer 150 may be completely deposited on the substrate 100 to cover the protective layer 140. Next, a plug process is performed. Semiconductor processes such as photolithography and etching processes may be performed to remove a portion of the dielectric layer 150, a portion of the protective layer 140, and a portion of the insulating layer 220 to form a hole 152 to expose the bottom electrode layer 210. Next, further semiconductor processes such as photolithography and etching processes are performed to remove a portion of the dielectric layer 150, a portion of the protective layer 140, and a portion of the insulating layer 250 to form a hole 156 to expose the middle electrode layer 240, and further semiconductor processes such as photolithography and etching processes are performed to remove a portion of the dielectric layer 150, a portion of the protective layer 140 and a portion of the dielectric layer 130 to form a hole 154 to expose the top electrode layer 230. Next, the holes 152, 154, and 156 are filled with conductive materials, and a planarization process is performed to form contacts CT1, CT2 and CT3 in the dielectric layer 150. The contact CT1 is electrically connected with the bottom electrode layer 210, the contact CT3 is electrically connected with the middle electrode layer 240, and the contact CT2 is electrically connected with the top electrode layer 230. The conductive materials of the contacts CT1, CT2 and CT3 may be the same or different. For other details of the contacts CT1, CT2 and CT3, reference may be made to the relevant description of the contacts CT1 and CT2 above. Thereby, the fabrication of the semiconductor device 1a is completed.

The aforementioned film layers, such as the liner 120, the bottom electrode layer 210, the insulating layers 220 and 250, the top electrode layer 230, the middle electrode layer 240, the dielectric layer 130, the protective layer 140, the dielectric layer 150 and the contacts CT1, CT2 and CT3, may be formed by any suitable methods. For example, the methods may be, but are not limited to, molecular-beam epitaxy (MBE), chemical vapor deposition (CVD), metal organic chemical vapor deposition (MOCVD), hydride vapor phase epitaxy (HVPE) and atomic layer deposition (ALD).

The main difference between the semiconductor device 1a and the semiconductor device 1 is that the structure of the capacitor structure 200a is different from that of the capacitor structure 200. The capacitor structure 200a includes a plurality of insulating layers. Herein, the number of the insulating layers is exemplary two, which are the insulating layer 220 and the insulating layer 250, respectively. The number of the electrode layers of the capacitor structure 200a is three, which are the bottom electrode layer 210, the middle electrode layer 240 and the top electrode layer 230, respectively. Each of the insulating layers 220 and 250 is disposed between two electrode layers. For example, the insulating layer 220 is disposed between the bottom electrode layer 210 and the middle electrode layer 240, and the insulating layer 250 is disposed between the middle electrode layer 240 and the top electrode layer 230. The contact CT1 and the contact CT2 may extend in the second horizontal direction D2 and be electrically connected with each other through a connecting portion (not shown) parallel to the first horizontal direction D1 (for example, the contacts CT1 and CT2 and the connecting portion together have a U-shaped shape in the top view), or the contact CT1 and the contact CT2 may be electrically connected through metal interconnections (not shown) disposed in other layers, so that the top layer electrode 230 and the bottom electrode layer 210 can be electrically connected with each other. Thereby, the top electrode layer 230 and the bottom electrode layer 210 together form a first electrode layer (not labeled), and the middle electrode layer 240 may be regarded as a second electrode layer. The sum of the overlapping area of the bottom electrode layer 210 and the middle electrode layer 240 and the overlapping area of the middle electrode layer 240 and the top electrode layer 230 may be regarded as the overlapping area of the first electrode layer and the second electrode layer. Compared with the capacitor structure 200 in FIG. 6, the overlapping area of the first electrode layer and the second electrode layer in the capacitor structure 200a is larger than the overlapping area of the bottom electrode layer 210 and the top electrode layer 230 in the capacitor structure 200. Therefore, the capacitor structure 200a can provide a larger capacitance value. In other embodiments, the number of insulating layers may be greater than or equal to three, and the number of electrode layers may be the number of insulating layers plus one, so that each insulating layer may be disposed between two electrode layers. For other details about the semiconductor device 1a, reference may be to the relevant description of the semiconductor device 1 above, and are not repeated herein.

Compared with the prior art, in the method for fabricating a semiconductor device according to the present disclosure, after forming a dielectric layer that directly covers the capacitor structure, a planarization process on the dielectric layer is omitted. Thereby, the peeling probability of the film layer subsequently deposited on the dielectric layer can be effectively reduced, and the performance and production yield of the semiconductor device may be improved. Furthermore, the process can be simplified by omitting the aforementioned planarization process, and the material and time costs required for the deposition of a sacrificial dielectric layer can be further omitted, which is beneficial to reduce production costs.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a trench formed in a substrate;
a capacitor structure disposed in the trench, the capacitor structure comprising:
a bottom electrode layer disposed in the trench and on a top surface of the substrate;
an insulating layer disposed on the bottom electrode layer; and
a top electrode layer disposed on the insulating layer; and
a dielectric layer disposed on the top electrode layer, wherein a portion of the dielectric layer is filled in the trench, and the dielectric layer comprises a recessed portion disposed above the trench.

2. The semiconductor device of claim 1, wherein the recessed portion has a V-shaped cross section.

3. The semiconductor device of claim 1, wherein the recessed portion has a width and a depth, and a ratio of the width to the depth is 1.5 to 1.9.

4. The semiconductor device of claim 1, wherein the capacitor structure comprises a first portion disposed in the trench and a second portion disposed on the top surface of the substrate, and a bottom of the recessed portion is lower than a bottom of the second portion of the capacitor structure.

5. The semiconductor device of claim 1, wherein a thickness of the dielectric layer ranges from 200 angstroms to 500 angstroms.

6. The semiconductor device of claim 1, wherein the dielectric layer is formed with a void, and the void is located in the trench.

7. The semiconductor device of claim 1, wherein the trench has a depth and a width, and a ratio of the depth to the width is 23 to 27.

8. The semiconductor device of claim 1, wherein a number of the trenches is at least two, and the capacitor structure is disposed in the least two trenches.

9. The semiconductor device of claim 1, wherein the dielectric layer partially covers the capacitor structure, and the semiconductor device further comprises:
a protective layer disposed on the dielectric layer and a portion of the capacitor structure not covered by the dielectric layer.

10. The semiconductor device of claim 9, wherein a material of the protective layer comprises a nitride.

11. A method for fabricating a semiconductor device, comprising:
forming a trench in a substrate;
forming a capacitor structure in the trench, comprising:
forming a bottom electrode layer in the trench and on a top surface of the substrate;
forming an insulating layer on the bottom electrode layer; and
forming a top electrode layer on the insulating layer; and
forming a dielectric layer on the top electrode layer, wherein a portion of the dielectric layer is filled in the trench, and the dielectric layer comprises a recessed portion disposed above the trench.

12. The method of claim 11, wherein the recessed portion has a V-shaped cross section.

13. The method of claim 11, wherein the recessed portion has a width and a depth, and a ratio of the width to the depth is 1.5 to 1.9.

14. The method of claim 11, wherein the capacitor structure comprises a first portion disposed in the trench and a second portion disposed on the top surface of the substrate, and a bottom of the recessed portion is lower than a bottom of the second portion of the capacitor structure.

15. The method of claim 11, wherein a thickness of the dielectric layer ranges from 200 angstroms to 500 angstroms.

16. The method of claim 11, wherein forming the dielectric layer on the top electrode layer comprises forming a void in the dielectric layer, and the void is located in the trench.

17. The method of claim 11, wherein the trench has a depth and a width, and a ratio of the depth to the width is 23 to 27.

18. The method of claim 11, wherein a number of the trenches is at least two, and the capacitor structure is disposed in the least two trenches.

19. The method of claim 11, further comprising:
removing a portion of the dielectric layer located outside the trench to expose a portion of the capacitor structure, and
forming a protective layer on the dielectric layer and the portion of the capacitor structure.

20. The method of claim 19, wherein a material of the protective layer comprises a nitride.
